(19) United States
(12) Patent Application Publication
(10) Pub. No.: US 2024/0235221 A9
(43) Pub. Date: Jul. 11, 2024

(54) BATTERY CHARGER INTEGRATED CIRCUIT FOR ADAPTIVELY LIMITING OVER-CURRENT, MOBILE DEVICE COMPRISING THE SAME AND OPERATION METHOD THEREOF

(71) Applicant: SAMSUNG ELECTRONICS CO., LTD., Suwon-si (KR)

(72) Inventors: Daewoong CHO, Suwon-si (KR); Kyeseok YOON, Suwon-si (KR); Seunghoon KIM, Suwon-si (KR); Jeongdu YOO, Suwon-si (KR); Sungwoo LEE, Suwon-si (KR); Jungwook HEO, Suwon-si (KR)

(73) Assignee: SAMSUNG ELECTRONICS CO., LTD., Suwon-si (KR)

(21) Appl. No.: 18/199,732

(22) Filed: May 19, 2023

(30) Foreign Application Priority Data
Oct. 25, 2022 (KR) 10-2022-0138102

(51) Int. Cl. H02J 7/00

(52) U.S. Cl. CPC H02J 7/00304; H02J 7/00714; H02J 7/007182

(57) ABSTRACT

A circuit includes: an overcurrent limiting (OCL) detector configured to detect whether a level of an inductor current reaches an OCL level and to generate an OCL detection voltage; a control loop circuit configured to generate a reset voltage by comparing a ramp voltage reflecting the level of the inductor current with an error voltage generated based on an operating condition that is out of a preset operating condition; an adaptive OCL controller configured to generate an OCL control current by counting a number of pulses of the OCL detection voltage and a number of pulses of the reset voltage; an oscillator configured to generate an oscillation voltage wherein a frequency of the oscillation voltage varies based on a magnitude of the overcurrent limit control current; and a switching transistor for switching the inductor current based on the oscillation voltage.

### CROSS-REFERENCE TO RELATED APPLICATION

This application claims priority under 35 U.S.C. § 119 to Korean Patent Application No. 10-2022-0138102 filed on Oct. 25, 2022, in the Korean Intellectual Property Office, the disclosure of which is incorporated by reference herein in their entireties.

### BACKGROUND

### 1. Field

Embodiments of the present disclosure described herein relates to a semiconductor device, and more particularly, to a battery charger integrated circuit that adaptively limits an overcurrent, a mobile device including the same, and an operation method thereof.

### 2. Description of Related Art

Recently, various types of mobile devices for communication or information exchange have been spread. A mobile device uses a rechargeable battery as a power source in order to provide an advantage of mobility. In general, when a mobile device is connected to a charger (e.g., a Travel Adapter (TA)) that enables battery charging, it operates in a charging mode (or a buck mode) for battery charging. On the other hand, when external devices are connected through a port such as a USB terminal, the mobile device also supports On-The-Go (OTG) mode (or a boost mode) to provide power to external devices using an internal battery. To this end, a charger Integrated Circuit (IC) (hereinafter “a charger IC”) for managing a charging mode and an OTG mode of a battery is used in a mobile device.

In a battery charger IC of a switching method that manages a charging current of a battery by switching an inductor current, an inductor current level limit is required to protect circuit elements. By sensing the level of the inductor current, an overcurrent limit (OCL) operation was applied. In this case, it can be implemented with a simple structure, but the amount of energy that can be transferred through the inductor is limited due to an OCL. In addition, there is a problem in that ripple of a large inductor current generated according to a switching operation occurs. Accordingly, there is a need for a battery charger IC capable of reducing a ripple of an inductor current in an OCL operation and increasing the amount of supplied energy.

### SUMMARY

Embodiments of the present disclosure provide a charger IC, a mobile device, and an operating method thereof capable of reducing the ripple of an inductor current in an overcurrent limit (OCL) operation and increasing the amount of supplied energy.

According to an aspect of the present disclosure, a battery charger integrated circuit for charging a battery, includes: an overcurrent limiting detector configured to detect whether a level of an inductor current reaches an overcurrent limiting level and to generate an overcurrent limiting detection voltage; a control loop circuit configured to generate a reset voltage by comparing a ramp voltage reflecting the level of the inductor current with an error voltage generated based on an operating condition that is out of a preset operating condition; an adaptive overcurrent limiting controller configured to generate an overcurrent limiting control current by counting a number of pulses of the overcurrent limiting detection voltage and a number of pulses of the reset voltage; an oscillator configured to generate an oscillation voltage wherein a frequency of the oscillation voltage varies based on a magnitude of the overcurrent limit control current; and a switching transistor for switching the inductor current based on the oscillation voltage.

According to another aspect of the present disclosure, an electronic device includes: an inductor supplying a charging current supplied from a charging terminal to a battery and a load; switching transistors configured to switch the inductor current flowing through the inductor based on a duty voltage and configured to transfer the inductor current as a battery current for charging the battery or a load current supplied to the load; and a battery charger integrated circuit configured to monitor a change in the load current and varying a switching frequency of the inductor current. The battery charger integrated circuit is configured to increase the switching frequency by counting a number of times that a level of the inductor current reaches an overcurrent limit level.

According to another aspect of the present disclosure, a method performed by a battery charger integrated circuit, the method includes: detecting an increase in a load current; increasing a duty cycle of a duty voltage for switching an inductor current in response to detecting the increase in the load current; detecting whether a level of the inductor current reaches a predetermined overcurrent limit level; and increasing a switching frequency of the duty voltage based on a number of consecutively reaching the predetermined overcurrent limit level of the inductor current, which reaches a predetermined reference number of times.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a mobile device including a battery charger Integrated Circuit (IC) according to an embodiment of the present disclosure;

FIG. 2 illustrates a configuration of a battery charger IC of the present disclosure;

FIG. 3 illustrates an example of the control loop circuit of FIG. 2;

FIG. 4 illustrates an overcurrent limit (OCL) detector of FIG. 2 as an example;

FIG. 5 illustrates each of the adaptive OCL controller and an oscillator of FIG. 2 in detail;

FIG. 6 illustrates an OCL Control Current (IOCL) adjusting operation of the adaptive OCL controller of FIG. 5 as an example;

FIG. 7 illustrates a switching frequency control process in the battery charger IC of the present disclosure;

FIG. 8 illustrates an operating method of the adaptive OCL controller of FIG. 5;

FIG. 9 illustrates a waveform diagram exemplarily showing the effect of the present disclosure; and

FIG. 10 illustrates a power system of a mobile device according to another embodiment of the present disclosure.

### DETAILED DESCRIPTION

It is to be understood that both the foregoing general description and the following detailed description are exemplary, and it is to be considered that an additional description of the claimed invention is provided. Reference signs are indicated in detail in preferred embodiments of the present disclosure, examples of which are indicated in the reference drawings. Wherever possible, the same reference numbers are used in the description and drawings to refer to the same or like parts.

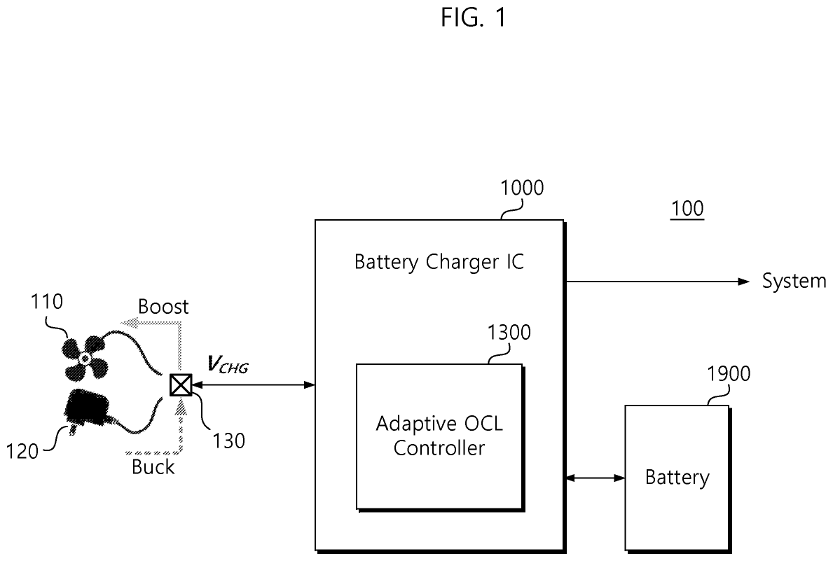

FIG. 1 is a block diagram showing a mobile device including a battery charger Integrated Circuit (IC) according to an embodiment of the present disclosure. In FIG. 1, a mobile device 100 according to the present disclosure may include a battery charger IC 1000 and a battery 1900 that adaptively perform overcurrent limiting.

The battery charger IC 1000 may operate in a buck mode or a boost mode according to a device connected to the charging terminal 130. For example, when a travel adapter 120 is connected to the charging terminal 130, the battery charger IC 1000 operates in a buck mode. That is, in the buck mode, the battery charger IC 1000 operates in a buck converter or charger mode in which the battery 1900 is charged by switching power provided through the travel adapter 120. On the other hand, when an On-The-Go (OTG) device 110 is connected to the charging terminal 130, the battery charger IC 1000 operates in a boost mode or OTG mode. That is, in the boost mode, the battery charger IC 1000 may switch power charged in the battery 1900 and provide the boosted voltage to the OTG device 110.

The battery charger IC 1000 may operate stably even in a charger mode or OTG mode under heavy load conditions. That is, the battery charger IC 1000 may stably supply load power to systems of the mobile device 100, such as an Application Processor (AP) memory, and storage, regardless of the operating mode. At this time, when the inductor current switched by the battery charger IC 1000 exceeds a saturation level, the battery charger IC 1000 may malfunction. Also, high inductor current may damage the battery charger IC 1000. Therefore, an overcurrent limit (OCL) operation is essential for the battery charger IC 1000 to prevent malfunction or damage.

The battery charger IC 1000 of the present disclosure includes an adaptive OCL controller 1300. The adaptive OCL controller 1300 may increase a switching frequency of the inductor current when the load current increases. At a fixed switching frequency, as in a related art, it is difficult to supply sufficient power to the required load. On the other hand, if the switching frequency of the inductor current is increased by the OCL controller 1300, maximum power transfer is possible within a range that does not violate the overcurrent limit. These advantages of the present disclosure will be explained in more detail through the drawings to be described later.

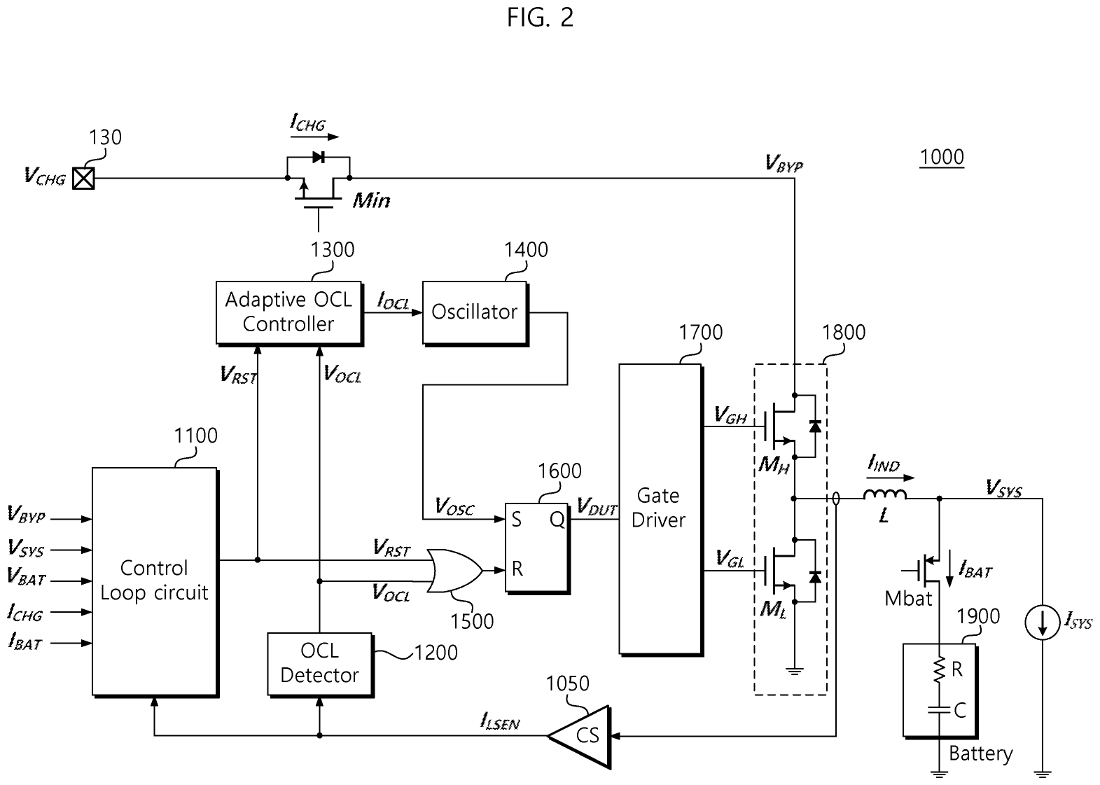

FIG. 2 is a block diagram showing the configuration of a battery charger IC of the present disclosure. In FIG. 2, the battery charger IC 1000 includes a control loop circuit 1100, an OCL detector 1200, an adaptive OCL controller 1300, an oscillator 1400, and an OR gate 1500, an SR latch 1600, a gate driver 1700, a switching transistor 1800, an inductor L, and a battery 1900.

The control loop circuit 1100 generates a reset voltage V_{RST} for maintaining a preset charging condition or a voltage output condition. For example, in a charger mode or a buck mode, a case in which at least one level of preset charging conditions (V_{BYP}, V_{SYS}, V_{BAT}, I_{CHG}, I_{BAT}) exceeds a set range (or a predetermined range) may occur. At this time, the control loop circuit 1100 generates a reset voltage V_{RST} as a control signal for reducing the inductor current I_{IND}.

Reset voltage V_{RST} drives the switching transistor 1800 to reduce inductor current I_{IND}. That is, when the reset voltage V_{RST} is provided at a high level, the duty voltage V_{DUT} transitions to a low level, and as a result, the first switching transistor MH is turned off and the second switching transistor ML is turned on. Accordingly, a level of the inductor current I_{IND} decreases.

In addition, in the OTG mode or the boost mode, when the level of the output voltage V_{CHG} of the charging terminal 130 exceeds a set condition (or a predetermined condition), the control loop circuit 1100 generates the reset voltage V_{RST} to reduce the inductor current I_{IND}. A specific configuration or function of the control loop circuit 1100 will be described in more detail through the drawings to be described later.

The OCL detector 1200 determines whether the inductor current reaches the OCL level based on the inductor detection current I_{LSEN} sensed by the current sensor 1050. The OCL detector 1200 generates an OCL detection voltage V_{OCL} based on the determination result. The OCL detection voltage V_{OCL} is delivered to the adaptive OCL controller 1300 and the OR gate 1500, respectively.

The adaptive OCL controller 1300 generates an OCL control current I_{OCL} for adjusting the switching frequency f_{sw} of the inductor current I_{IND} based on the reset voltage V_{RST} and the OCL detection voltage V_{OCL}. For example, the adaptive OCL controller 1300 may increase the level of the OCL control current I_{OCL} when the OCL detection voltage V_{OCL} continuously occurs more than a reference number of times (select one (1) among above/below).

When the level of the OCL control current I_{OCL} increases, the switching frequency f_{SW} of the oscillation voltage V_{OSC} generated by the oscillator 1400 increases. As the frequency of the oscillation voltage V_{OSC} increases, the switching frequency f_{Sw} or a switching speed of the switching transistor 1800 increases. When the switching frequency f_{Sw} of the switching transistor 1800 increases, the ripple of the inductor current I_{IND} delivered to the system becomes relatively small, and the average inductor current Ism increases. Thus, the amount of energy provided to the system is relatively increased.

On the other hand, the adaptive OCL controller 1300 reduces the OCL control current I_{OCL} when the continuously occurring reset voltage V_{RST} is greater than or equal to a reference number of times (select one (1) among above/below). When the level of the OCL control current I_{OCL} decreases, the frequency of the oscillation voltage V_{OSC} generated by the oscillator 1400 decreases. As the frequency of the oscillation voltage V_{OSC} decreases, the switching frequency f_{sw} or the switching speed of the switching transistor 1800 slows down. When the switching frequency f_{sw} of the switching transistor 1800 is lowered, the ripple of the inductor current I_{IND} delivered to the system becomes relatively large, and the average inductor current I_{IND} decreases.

The oscillator 1400 generates an oscillation voltage V_{OSC} having a variable frequency according to the level of the OCL control current I_{OCL} provided by the adaptive OCL controller 1300. The oscillator 1400 may determine the rising slope of the node voltage V_{SAW} through the OCL control current I_{OCL}. If the OCL control current I_{OCL} is large, the node voltage V_{SAW} increases rapidly.

Also, when the node voltage V_{SAW} reaches the reference level, the oscillator 1400 generates a pulse-shaped oscillation voltage V_{OSC}. Therefore, when the OCL control current I_{OCL} is large, the generation frequency or frequency of the oscillation voltage V_{OSC} increases. As a result, as the OCL control current I_{OCL} increases, the switching frequency f_{sw} of the duty voltage V_{DUT} generated based on the oscillation voltage V_{OSC} also increases. Then, the switching speed of the inductor current I_{IND} is increased by the duty voltage V_{DUT}. The structure of the oscillator 1400 will be described in more detail through drawings to be described later.

The OR gate 1500 resets the SR latch 1600 when any one of the reset voltage V_{RST} and the OCL detection voltage V_{OCL} is activated. That is, the OR gate 1500 resets the SR latch 1600 when any one of the reset voltage V_{RST} and the OCL detection voltage V_{OCL} becomes high, and as a result, the duty voltage V_{DUT} can be transitioned to a low level. When the duty voltage V_{DUT} transitions to a low level, the first switching transistor MH of the switching transistor 1800 is turned off and the second switching transistor ML is turned on. Accordingly, the OR gate 1500 determines a falling point or duty cycle of the duty voltage V_{DUT} to reduce the inductor current I_{IND}.

The SR latch 1600 generates a duty voltage V_{DUT} for driving the gate driver 1700 or the switching transistor 1800. The duty voltage V_{DUT} generates a duty voltage V_{DUT}. A duty cycle of the duty voltage V_{DUT} is determined by the oscillation voltage V_{OSC}, the reset voltage V_{RST}, and the OCL detection voltage V_{OCL}. That is, the duty voltage VD U T transitions to a high level in synchronization with the oscillation voltage V_{OSC} provided to the set input ‘S’ of the SR latch 1600. Also, the duty voltage V_{DUT} transitions to a low level in synchronization with the reset voltage V_{RST} or the OCL detection voltage V_{OCL}.

The gate driver 1700 generates gate control signals V_{GH} and V_{GL} for driving the switching transistor 1800 including power switches, based on the duty voltage V_{DUT}. The gate driver 1700 may generate gate control signals V_{GH} and V_{GL} having a sufficient level to drive the switching transistor 1800 operating at a relatively high voltage.

The switching transistor 1800 may include a first switching transistor MH and a second switching transistor ML. The first switching transistor MH supplies the charging current I_{CHG} to the inductor L to increase the inductor current I_{IND} supplied to the system through the inductor L. On the other hand, the second switching transistor ML connects or blocks one end of the inductor L and the ground in order to reduce the inductor current I_{IND} supplied to the system through the inductor L. The first switching transistor MH and the second switching transistor ML may be implemented as a power Metal-Oxide-Semiconductor Field-Effect Transistor (MOSFET) usable as a switching element.

The battery 1900 may be built into the mobile device 100. In one embodiment, the battery 1900 may be detachable from the mobile device 100. The battery 1900 may include one or a plurality of battery cells. A plurality of battery cells may be connected in series or parallel. The battery switch Mbat constituting an input terminal or an output terminal of the battery 1900 is shown as a PMOS transistor, but the present disclosure is not limited thereto. For example, it will be appreciated that the battery switch Mbat may be implemented with an NMOS transistor or other type of switch element.

As described above, the battery charger IC 1000 according to an embodiment of the present disclosure counts the number of times that the magnitude of the inductor current I_{IND} reaches the OCL level to determine the switching frequency f_{SW} of the inductor current I_{IND}. When the switching frequency f_{SW} is fixed, the average value of the switched inductor current I_{IND} cannot increase due to the OCL, making it difficult to supply sufficient power to the load. On the other hand, as the switching frequency f_{sw} changes, the fluctuation of the switched inductor current I_{IND} decreases, but the average value increases. Accordingly, it is possible to provide a relatively higher average value of inductor current I_{IND}, so that sufficient power required can be supplied to the load even in the presence of an OCL.

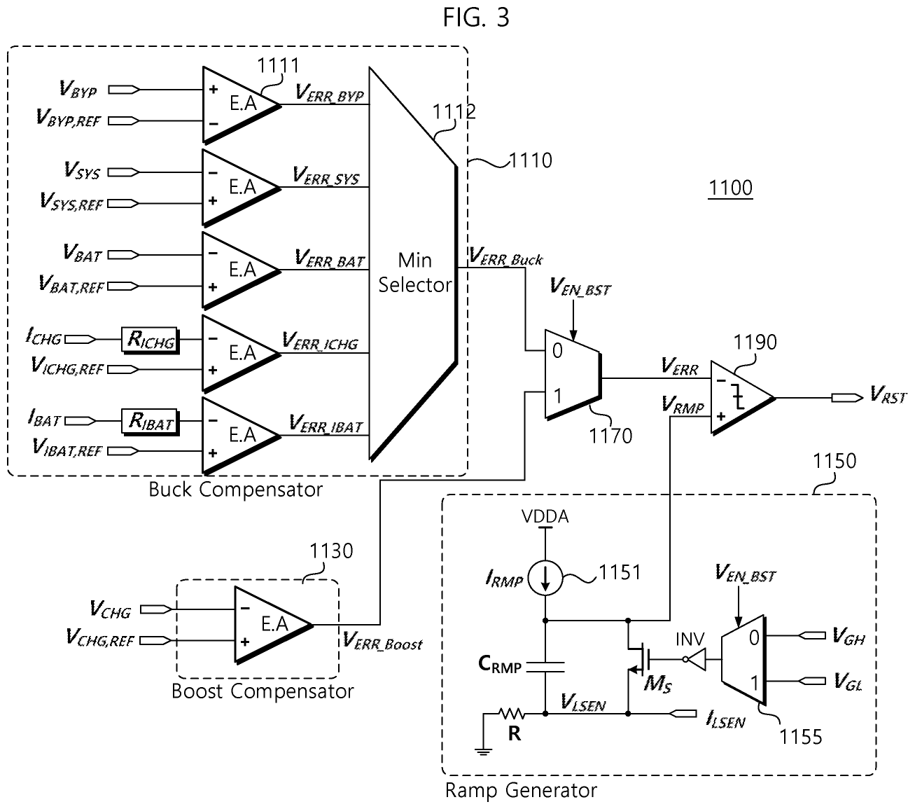

FIG. 3 is a circuit diagram showing an example of the control loop circuit of FIG. 2. In FIG. 3, the control loop circuit 1100 may include a buck compensator 1110, a boost compensator 1130, a ramp generator 1150, a multiplexer 1170, and a comparator 1190. The buck compensator 1110 and the boost compensator 1130 generate an error voltage V_{ERR} when the preset charging conditions (V_{BYP}, V_{SYS}, V_{BAT}, I_{CHG} and I_{BAT}) or output voltage V_{CHG} conditions are exceeded in the buck mode or boost mode. On the other hand, the ramp generator 1150 generates the ramp voltage V_{RMP} reflecting the sensing result I_{LSEN} of the inductor current I_{IND}.

The buck compensator 1110 generates an error voltage V_{ERR_Buck} by monitoring charging conditions (V_{BYP}, V_{SYS}, V_{BAT}, I_{CHG} and I_{BAT}) when operating in a charging mode or a buck mode. For example, when the bypass voltage V_{BYP} of the switching transistor 1800 rises beyond a reference value in the charging mode, this state is monitored by the error amplifier 1111 and an error voltage V_{ERR_BYP} is generated. Then, the output of the error amplifier 1111 is selected by the selector 1112 and transmitted to the multiplexer 1170. The multiplexer 1170 will select ‘0’ input and pass it to the comparator 1190 in the charging mode. As such, in the charging mode, the buck compensator 1110 selects one of the charging conditions (V_{BYP}, V_{SYS}, V_{BAT}, I_{CHG} and I_{BAT}) that exceeds or falls short of the reference value to generate the error voltage V_{ERR}, and comparator 1190 to trigger the generation of the reset voltage V_{RST}. When the reset voltage V_{RST} is generated, the inductor current I_{IND} is reduced by switching.

The boost compensator 1130 monitors the charging voltage V_{CHG} generated at the charging terminal 130 in the boost mode. When the charging voltage V_{CHG} rises excessively and exceeds the reference level V_{CHG,REF}, the error amplifier E.A of the boost compensator 1130 generates an error voltage V_{ERR_Boost}. Then, the multiplexer 1170 selects the ‘1’ input and passes it to the comparator 1190 in the boost mode. The comparator 1190 compares the error voltage V_{ERR_Boost} with the ramp voltage V_{RMP} to generate the reset voltage V_{RST}. When the reset voltage V_{RST} is generated, the inductor current I_{IND} decreases due to switching, and the level of the charging voltage V_{CHG} also decreases.

The ramp generator 1150 generates the ramp voltage V_{RMP} for comparison with the error voltage V_{ERR} in the comparator 1190. To generate the ramp voltage V_{RMP}, the ramp generator 1150 includes a ramp current source 1151, a capacitor C_{RMP}, a resistor R, a multiplexer 1155, an inverter INV, and a switch transistor M_{S}. The procedure for generating the ramp voltage V_{RMP} is as follows.

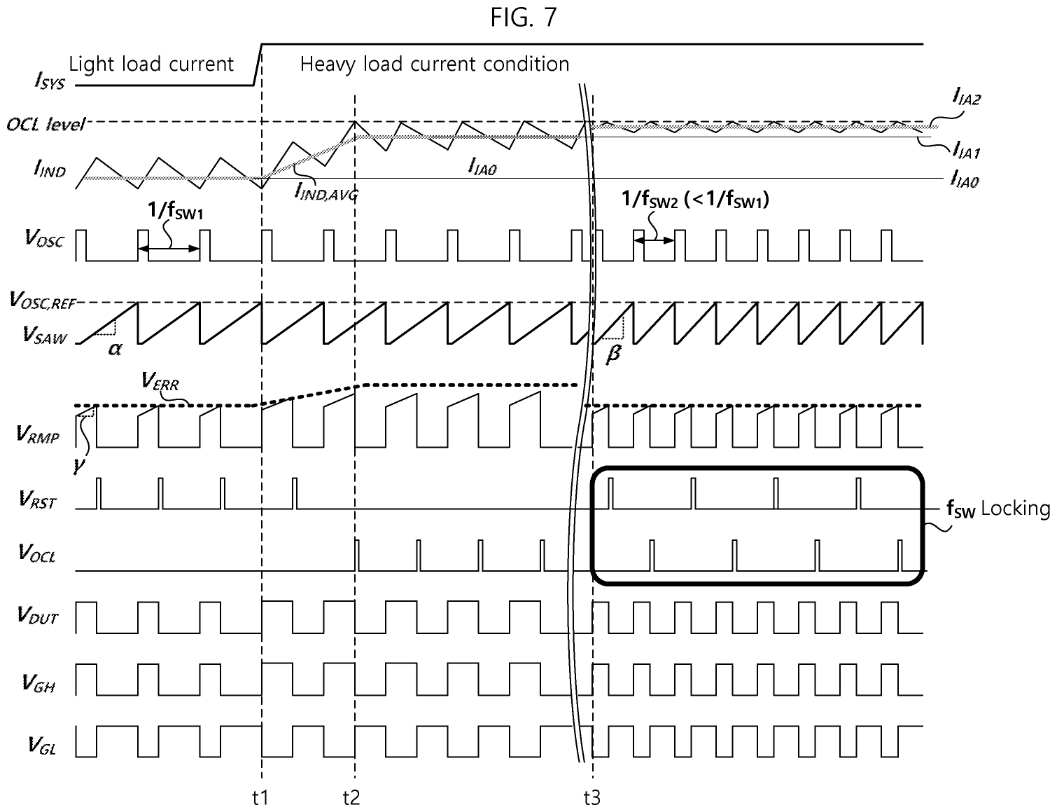

First, the sensing current I_{LSEN} provided as a result of sensing the magnitude of the inductor current END is fed back and transmitted to the ramp generator 1150. Then, the sensing current I_{LSEN} is converted into the sensing voltage V_{LSEN} by the resistor R. Subsequently, when the ramp capacitor C_{RMP} is charged by the ramp current I_{RMP} supplied from the ramp current source 1151, the ramp voltage V_{RMP} is obtained by adding the sensing voltage V_{LSEN} and the voltage formed in the ramp capacitor C_{RMP}. In a period in which charges are charged by the ramp capacitor C_{RMP}, the ramp voltage V_{RMP} has a ramp waveform rising with a predetermined slope. The multiplexer 1155 selects the gate control signal V_{GL} for controlling the second switching transistor ML provided to the ‘1’ input terminal in the boost mode. On the other hand, the multiplexer 1155 selects the gate control signal V_{GH} that controls the first switching transistor MH provided to the ‘0’ input terminal in the buck (or charge) mode. Currently, when the ramp generator 1150 is operating in the buck mode, the gate control signal V_{GH} is selected and inverted by the inverter INV to turn on the switch transistor Mₛ. When the gate control signal V_{GH} falls, the ramp voltage V_{RMP} stops rising and is discharged. The waveform of the ramp voltage V_{RMP} provided by the ramp generator 1150 will be described in detail with reference to FIG. 7 described below.

The multiplexer 1170 selects the error voltage V_{ERR} according to the mode. In the boost mode, the multiplexer 1170 selects the error voltage V_{ERR} from the boost compensator 1130 provided to the ‘1’ input terminal and transfers it to the comparator 1190. On the other hand, in the buck (or charge) mode, the multiplexer 1170 selects the error voltage V_{ERR} from the buck compensator 1110 provided to the ‘0’ input terminal and transfers it to the comparator 1190.

The comparator 1190 compares the error voltage V_{ERR} with the ramp voltage Vin to generate the reset voltage V_{RST}. At a point in time when the ramp voltage V_{RMP}, which increases with the ramp waveform, becomes higher than the error voltage V_{ERR}, the comparator 1190 generates a pulse-shaped reset voltage V_{RST}. Accordingly, when the ramp voltage V_{RMP} does not reach the error voltage V_{ERR} within one cycle, there is a case in which the pulse of reset voltage V_{RST} does not occur. For example, generation of the reset voltage V_{RST} may be omitted in a period in which the inductor current I_{IND} gradually increases. Instead, the drop of the duty voltage V_{DUT} may be controlled by the OCL detection voltage V_{OCL} generated according to the increase of the inductor current I_{IND}.

In the above, an exemplary configuration of the control loop circuit 1100 of the present disclosure has been described. The ramp voltage V_{RMP} and the error voltage V_{ERR} are provided by the control loop circuit 1100. The control loop circuit 1100 generates the reset voltage V_{RST} using the ramp voltage V_{RMP} and the error voltage V_{ERR}. The reset voltage V_{RST} is provided to the adaptive OCL controller 1300 of the present disclosure and is also used as a source for controlling the frequency of the oscillation voltage V_{OSC}.

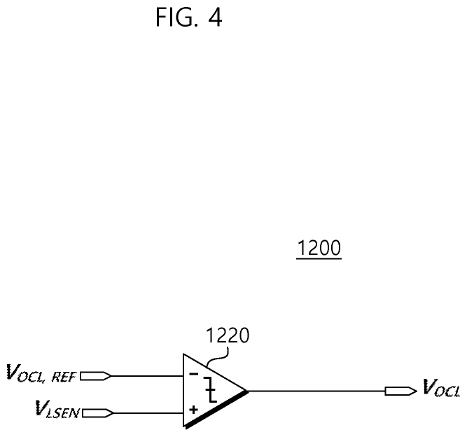

FIG. 4 is a circuit diagram showing the OCL detector of FIG. 2 as an example. In FIG. 4, the OCL detector 1200 generates an OCL detection voltage Voce, from a comparison result between a detection voltage V_{LSEN} provided as a result of sensing the inductor current I_{IND} and an OCL reference voltage V_{OCL,REF}.

Here, the sensing voltage V_{LSEN} has a voltage level corresponding to the magnitude of the sensing current I_{LSEN} generated from the sensing result of the inductor current I_{IND}. Accordingly, by selecting appropriate OCL reference voltages V_{OCL,REF}, the OCL detector 1200 may determine whether the magnitude of the inductor current I_{IND} reaches the OCL level.

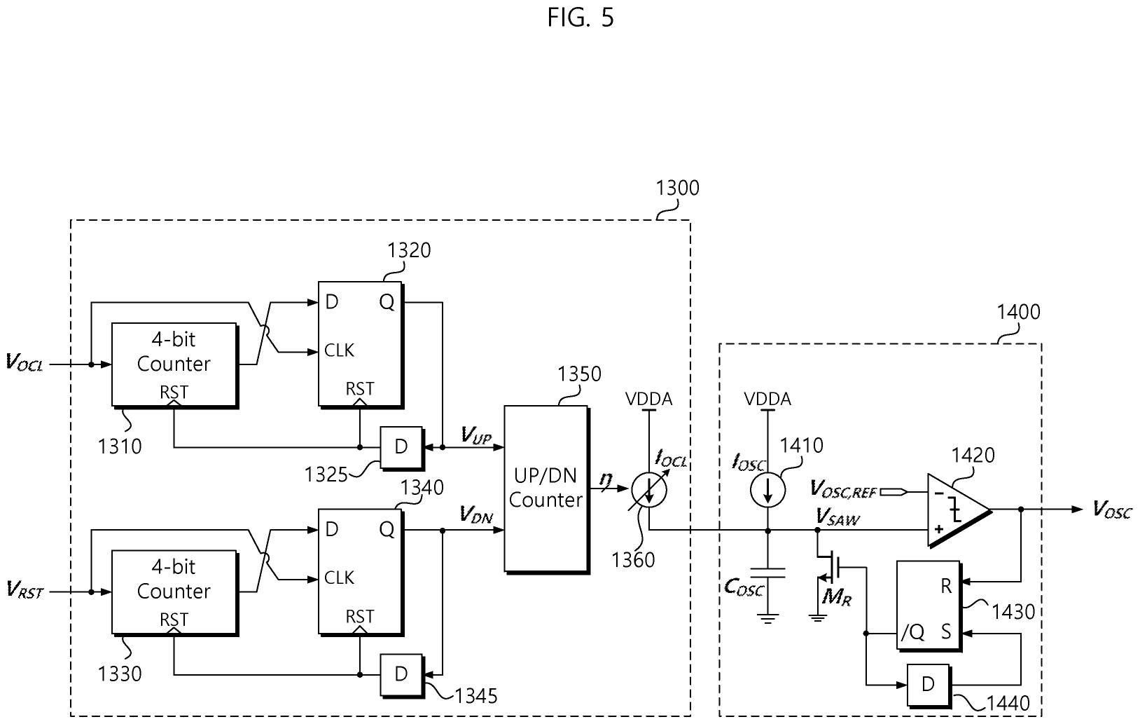

FIG. 5 illustrates each of the adaptive OCL controller and oscillator of FIG. 2 in detail. In FIG. 5, the adaptive OCL controller 1300 includes 4-bit counters 1310 and 1330, D-flip-flops 1320 and 1340, delays 1325 and 1345, and an up-and-down counter 1350, and a variable current source 1360. The oscillator 1400 may include an oscillation current source 1410, a comparator 1420, an SR latch 1430, a delay 1440, a discharge switch M_{R}, and an oscillation capacitor C_{OSC}.

The adaptive OCL controller 1300 increases the size of the OCL control current I_{OCL} of the variable current source 1360 when the number of consecutive occurrences of the OCL detection voltage V_{OCL} exceeds the reference number. The adaptive OCL controller 1300 reduces the size of the OCL control current I_{OCL} of the variable current source 1360 when the number of consecutive occurrences of the reset voltage V_{RST} exceeds the reference number.

To this end, the 4-bit counter 1310 may count the number of consecutive occurrences of the OCL detection voltage V_{OCL}. When the OCL detection voltage Vou continuously occurs 16 times, the 4-bit counter 1310 transitions the data input terminal ‘D’ of the D flip-flop 1320 to a high level. Then, the data output terminal ‘Q’ of the D flip-flop 1320 is output at a high level, and the up voltage V_{UP} is provided at a high level to count up the up-and-down counter 1350. Subsequently, the 4-bit counter 1310 and the D flip-flop 1320 are reset by the delay 1325. Here, the 4-bit counter 1310 may be modified into various bit sizes as needed. For example, if the 4-bit counter 1310 is replaced with a 3-bit counter, the up-and-down counter 1350 will be counted up when the OCL detection voltage V_{OCL} occurs 8 times consecutively.

Also, the 4-bit counter 1330 may count the number of consecutive occurrences of the reset voltage V_{RST}. When the reset voltage V_{RST} occurs 16 times consecutively, the 4-bit counter 1330 transitions the data input terminal ‘D’ of the D flip-flop 1340 to a high level. Then, the data output terminal ‘Q’ of the D flip-flop 1340 is output at a high level, and the up-and-down counter 1350 is counted down by the down voltage V_{DN} of the high level. Subsequently, the 4-bit counter 1330 and the D flip-flop 1340 are reset by the delay 1345. Here, the 4-bit counter 1330 may also be changed to the same bit size as the 4-bit counter 1310.

The up-and-down counter 1350 counts up or down a predetermined bit value based on the up voltage V_{UP} and the down voltage V_{DN}. The size of the OCL control current I_{OCL} generated by the variable current source 1360 may be increased or decreased according to the count value ‘n’ of the up-and-down counter 1350. As a result, when pulses of the OCL detection voltage V_{OCL} are continuously generated 16 times, the magnitude of the OCL control current I_{OCL} increases. On the other hand, when the reset voltage V_{RST} is continuously generated 16 times, the size of the OCL control current I_{OCL} decreases.

The oscillator 1400 generates an oscillation voltage V_{OSC}. A frequency of the oscillation voltage V_{OSC} varies based on the magnitude of the OCL control current I_{OCL}. The oscillation current source 1410 provides an oscillation current I_{OSC} for charging the oscillation capacitor C_{OSC}. As the oscillation capacitor C_{OSC} is charged by the oscillation current I_{OSC}, the node voltage V_{SAW} formed across the oscillation capacitor C_{OSC} is generated as a ramp waveform or a sawtooth waveform with a constant slope.

When the node voltage V_{SAW} rises and reaches the oscillation reference voltage V_{OSC,REF}, the oscillation voltage V_{OSC} is generated by the comparator 1420. The oscillation voltage V_{OSC} is formed as a pulse voltage by the SR latch 1430, the delay 1440, and the discharge switch M_{R}. That is, when the oscillation voltage V_{OSC} is output to a high level, the reset input terminal of the SR latch 1430 is set to a high level, and the inverted output terminal ‘/Q’ also transitions to a high level. Then, the discharge switch M_{R} is turned on and the node voltage V_{SAW} formed across both ends of the oscillation capacitor C_{OSC} is lowered to the ground level by discharging. The delay 1440 delays the inverting output terminal ‘/Q’ to transition the SR latch 1430 to the set state. Then, the discharge switch M_{R} is turned off again, and the node voltage V_{SAW} starts to rise.

The switching frequency f_{SW} of the inductor current Ism can be varied by the adaptive OCL controller 1300 and the oscillator 1400 of the present disclosure. Through the adjustment of the switching frequency f_{SW}, it is possible to supply a sufficient amount of energy to the load despite the limitation of the OCL level. Therefore, it is possible to provide a load current supply capability that cannot be achieved only by adjusting the duty cycle of the duty voltage V_{DUT} driving the switching transistors 1800 (see FIG. 2) through the adaptive OCL controller 1300 and the oscillator 1400.

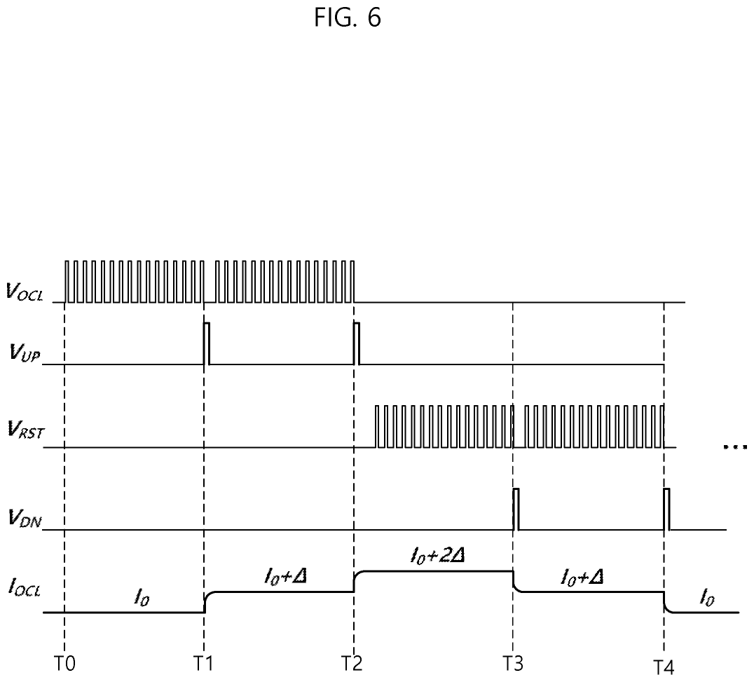

FIG. 6 is a timing diagram illustrating an OCL control current I_{OCL} adjusting operation of the adaptive OCL controller of FIG. 5 as an example. In FIG. 6, the adaptive OCL controller 1300 may increase or decrease the OCL control current I_{OCL} according to the number of consecutive occurrences of the OCL detection voltage V_{OCL} or the reset voltage V_{RST}.

At time T0, as the level of the inductor current I_{IND} increases to reach the OCL level, the OCL detection voltage V_{OCL} starts to be generated. However, the count of the 4-bit counter 1310 of the adaptive OCL controller 1300 has only started, and the value of the up-and-down counter 1350 has not changed. Accordingly, the OCL control current I_{OCL} generated by the variable current source 1360 maintains the initial value ‘I₀’. The OCL detection voltage V_{OCL} continuously occurs 16 times until the time point T1.

At time T1, the count value of the 4-bit counter 1310 reaches ‘1111’ according to 16 consecutive occurrences of the OCL detection voltage V_{OCL} from time TO. Then, a pulse of the up voltage V_{UP} is generated by the first D flip-flop 1320. Synchronized with the generation of the up voltage V_{UP}, the up-and-down counter 1350 counts up. According to the count-up of the up-and-down counter 1350, the OCL control current I_{OCL} generated from the variable current source 1360 is generated with a size increased by a predetermined step ‘A’ from the initial value ‘I₀’.

At time T2, the count value of the 4-bit counter 1310 is counted up from ‘0000’ to ‘1111’ as the OCL detection voltage V_{OCL} additionally occurs continuously 16 times from time T1 to time T2. Then, a pulse of the second up voltage V_{UP} is generated by the first D flip-flop 1320. Synchronized with the generation of the up voltage V_{UP}, the up-and-down counter 1350 is counted up again. As the up-and-down counter 1350 counts up, the OCL control current I_{OCL} generated from the variable current source 1360 increases to ‘I₀+2Δ’.

From time T2 to time T3, as the reset voltage V_{RST} occurs 16 times in succession, the count value of the 4-bit counter 1330 counts up from ‘0000’ to ‘1111’. Then, the first down voltage V_{DN} pulse is generated by the D flip-flop 1340. Synchronized with the occurrence of the first down voltage V_{DN}, the up-and-down counter 1350 counts down from the previous count value. As the up-and-down counter 1350 counts down, the magnitude of the OCL control current I_{OCL} generated from the variable current source 1360 decreases to ‘I₀+Δ’.

From time T3 to time T4, as the reset voltage V_{RST} occurs again 16 times in succession, the count value of the 4-bit counter 1330 counts up from ‘0000’ to ‘1111’. Then, a second down voltage V_{DN} pulse is generated by the D flip-flop 1340 at the time T4. Synchronized with the generation of the second down voltage V_{DN}, the up-and-down counter 1350 counts down from the previous count value. As the up-and-down counter 1350 counts down, the magnitude of the OCL control current I_{OCL} generated from the variable current source 1360 decreases to ‘I₀’.

In the above descriptions, the method of generating the OCL control current I_{OCL} of the adaptive OCL controller 1300 has been described as an example. The adaptive OCL controller 1300 generates an OCL control current I_{OCL} having a variable level based on the number of consecutive occurrences of the OCL detection voltage V_{OCL} or the reset voltage V_{RST}. The frequency of the oscillation voltage V_{OSC} or the switching frequency f_{SW} may be adjusted according to the increase or decrease of the OCL control current I_{OCL}.

FIG. 7 illustrates a switching frequency control process in the battery charger IC of the present disclosure. In FIG. 7, the frequency of the oscillation voltage V_{OSC} increases when the load current I_{SYS} increases so that more power delivery to the system is required.

Before time t1, the battery charger IC 1000 is in a light load current condition. In addition, the load current I_{SYS} required by the system of the mobile device 100 rises at the time point t1. That is, the battery charger IC 1000 is in a heavy load current condition after time t1.

Under light load current conditions, the magnitude of the inductor current I_{IND} will not reach the OCL level even though there is ripple due to switching. At this time, although ripples exist in the inductor current I_{IND} due to switching, the average inductor current I_{IND,AVG} maintains a low state ‘I_{IA0}’. Accordingly, the reset voltage V_{RST} of the control loop circuit 1100 is generated according to a comparison result between the error voltage V_{ERR} and the ramp voltage V_{RMP}. That is, whenever the ramp voltage V_{RMP} reaches the error voltage V_{ERR}, a reset voltage V_{RST} pulse is generated.

The number of pulses of the reset voltage V_{RST} may be accumulated and counted by the adaptive OCL controller 1300. Also, since there is no increase or decrease in the OCL control current I_{OCL} before the time t1, the slope of the node voltage V_{SAW} of the oscillator 1400 will maintain the ‘a’ value. The slope of the node voltage V_{SAW} ‘α’ may be expressed by Equation 1 below.

$$α = \frac{{I}_{OSC}}{{C}_{OSC}} \qquad [ Equation 1 ]$$

Here, ‘I_{OSC}’ represents the magnitude of the oscillation current that sets the basic slope, and ‘C_{OSC}’ represents the capacity of the oscillation capacitor for charging the current (see FIG. 5). In this state, the frequency of the oscillation voltage V_{OSC} generated by the oscillator 1400 corresponds to the first switching frequency f_{SW1}.

At the time t1, the load current I_{SYS} required by the system increases. As a result, when more power delivery to the load is required, the magnitude of the inductor current END increases and reaches to the OCL level. Then, the error voltage V_{ERR} in the control loop circuit 1100 increases. The reset voltage V_{RST} of the control loop circuit 1100 is generated according to a comparison result between the error voltage V_{ERR} and the ramp voltage V_{RMP}. Therefore, as the error voltage V_{ERR} becomes higher than the ramp voltage V_{RMP}, the reset voltage V_{RST} cannot be generated.

Instead, an OCL detection voltage V_{OCL} pulse generated when the magnitude of the inductor current I_{IND} reaches the OCL level in the OCL detector 1200 is generated. The OCL detection voltage V_{OCL} pulse starts to occur at time t2. The number of continuously occurring OCL detection voltage V_{OCL} pulses may be accumulated and counted by the adaptive OCL controller 1300. The number of OCL detection voltage V_{OCL} pulses has not yet reached the count value that increases the OCL control current I_{OCL}. Accordingly, the slope of the node voltage V_{SAW} for generating the sawtooth wave of the oscillator 1400 will maintain the ‘a’ value. In this state, the frequency of the oscillation voltage V_{OSC} generated by the oscillator 1400 may still maintain the first switching frequency ‘fSW1’. However, the number of counted OCL detection voltage V_{OCL} pulses gradually increases, and a count value that increases the OCL control current I_{OCL} will be reached.

After the time point t3, waveforms after the number of OCL detection voltage V_{OCL} pulses reach a count value (e.g., 16) for increasing the OCL control current I_{OCL} are shown. When the number of OCL detection voltage V_{OCL} pulses reaches the count value (e.g., 16) that increases the OCL control current I_{OCL}, the slope of the node voltage V_{SAW} for generating the sawtooth wave of the oscillator 1400 is ‘β (>α)’. The slope of the node voltage V_{SAW} ‘β’ may be expressed by Equation 2 below.

$$β = \frac{{I}_{OSC} + {I}_{OCL}}{{C}_{OSC}} \qquad [ Equation 2 ]$$

Here, ‘I_{OSC}’ represents the size of the oscillation current that sets the basic slope, ‘C_{OSC}’ represents the capacity of the oscillation capacitor for charging the current, and ‘I_{OCL}’ represents the size of the OCL control current (see FIG. 5). The frequency of the oscillation voltage V_{OSC} generated by the oscillator 1400 increases to the second switching frequency ‘f_{SW2}’ as the slope of the node voltage V_{SAW} increases. And, as the second switching frequency ‘f_{SW2}’ increases, the error voltage V_{ERR} decreases again. Generation of the reset voltage V_{RST} starts again by the lowered error voltage V_{ERR}.

In addition, the OCL detection voltage V_{OCL} pulse by the OCL detector 1200 is also generated by the increase of the switching frequency and the increased average inductor current That is, the OCL detection voltage V_{OCL} pulse generated when the inductor current I_{IND} reaches the OCL level is alternately generated with the reset voltage V_{RST} pulse. In this case, the number of counts of each of the reset voltage V_{RST} and the OCL detection voltage V_{OCL} in the adaptive OCL controller 1300 cannot reach a level at which the OCL control current I_{OCL} is varied. That is, the frequency of the oscillation voltage V_{OSC} generated by the oscillator 1400 is locked to the switching frequency ‘f_{SW2}’ formed at the time t3.

As the switching frequency ‘f_{SW2}’ is fixed at a higher value, the size of ripple due to switching of the inductor current I_{IND} decreases. In addition, the level of the average inductor current ‘I_{IA2}’ is also increased than before the time point t1 to approach the overcurrent limit level. This may indicate that more power can be delivered by increasing the amount of current delivered to the system or load.

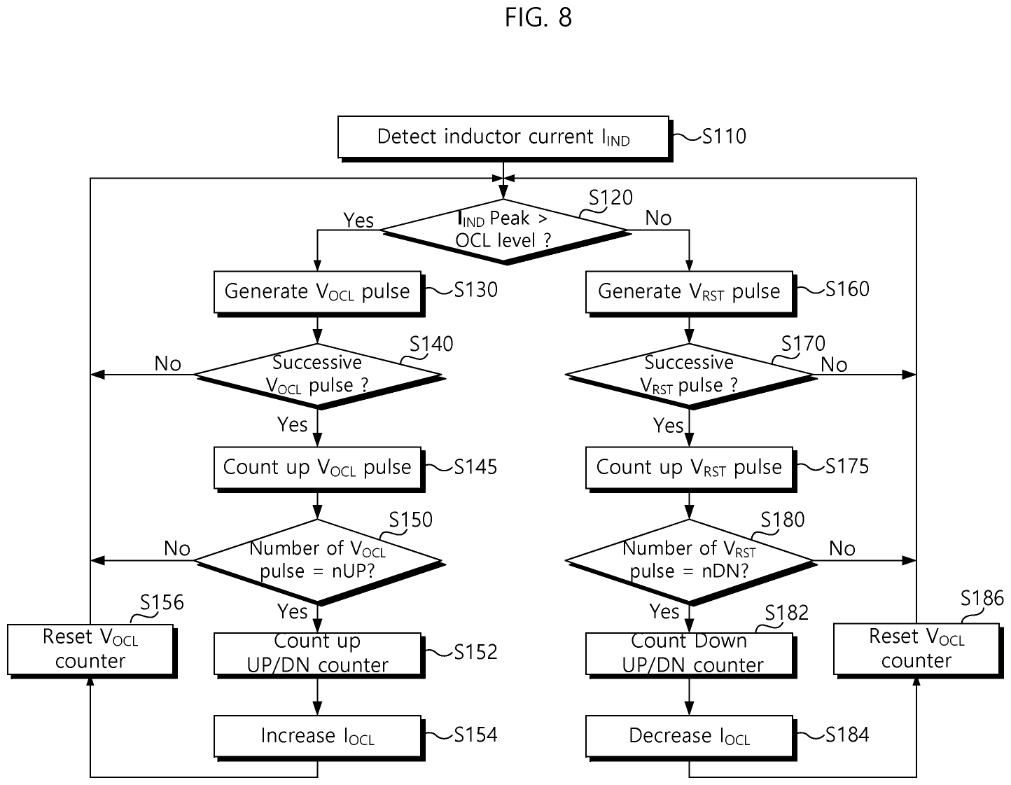

FIG. 8 illustrates an operating method of the adaptive OCL controller of FIG. 5. In FIG. 8, the adaptive OCL controller 1300 generates an OCL control current I_{OCL} in response to a reset voltage V_{RST} from the control loop circuit 1100 and an OCL detection voltage V_{OCL} from the OCL detector 1200. Then, the oscillator 1400 may generate an oscillation voltage V_{OSC} having a switching frequency that varies based on the OCL control current I_{OCL}.

In operation S110, the OCL detector 1200 senses the inductor current I_{IND}. Detection of the magnitude of the inductor current I_{IND} by the OCL detector 1200 may be performed using separate devices such as, for example, the current sensor 1050 (see FIG. 2).

In operation S120, an operation branch occurs according to a comparison result between the magnitude of the detected inductor current I_{IND} peak and the OCL level. If the magnitude of the inductor current I_{IND} peak is greater than the OCL level (‘Yes’ direction), the procedure moves to operation S130. On the other hand, if the magnitude of the detected inductor current I_{IND} peak is not greater than the OCL level (‘No’ direction), the procedure moves to operation S160.

In operation S130, when the peak level of the sensed inductor current I_{IND} is greater than the OCL level, the OCL detector 1200 generates an OCL detection voltage V_{OCL} pulse.

In operation S140, it is checked whether OCL detection voltage V_{OCL} pulses are continuously generated. If OCL detection voltage V_{OCL} pulses continuously occur (‘Yes’ direction), the process moves to operation S145. On the other hand, when OCL detection voltage V_{OCL} pulses are not continuously generated (No′ direction), the procedure returns to operation S120.

In operation S145, the number of consecutive OCL detection voltage V_{OCL} pulses is counted. For example, a 4-bit counter may be used as an element for counting the number of consecutive OCL detection voltage V_{OCL} pulses.

In operation S150, it is checked whether the number of consecutive OCL detection voltage V_{OCL} pulses reaches the maximum value ‘nUP’. When counting the number of OCL detection voltage V_{OCL} pulses using a 4-bit counter, the maximum value ‘nUP’ may be 16 (=24). If the number of OCL detection voltage V_{OCL} pulses reaches the maximum value ‘nUP’ (‘Yes’ direction), the process moves to operation S152. On the other hand, if the number of OCL detection voltage V_{OCL} pulses does not reach the maximum value ‘nUP’ (direction ‘No’), the process returns to operation S120.

In operation S152, the up-and-down counter 1350 of the adaptive OCL controller 1300 is counted up.

In operation S154, when the up-and-down counter 1350 of the adaptive OCL controller 1300 counts up, the up-and-down counter 1350 increases the size of the OCL control current I_{OCL} of the variable current source 1360.

In operation S156, the OCL pulse counter is reset and the procedure returns to operation S120.

In operation S160, since the magnitude of the inductor current Iii does not reach the OCL level, a reset voltage V_{RST} pulse is generated by the control loop circuit 1100. The reset voltage V_{RST} of the control loop circuit 1100 is generated according to a comparison result between the error voltage V_{ERR} and the ramp voltage V_{RMP}. That is, whenever the ramp voltage V_{RMP} reaches the error voltage V_{ERR}, a reset voltage V_{RST} pulse is generated.

In operation S170, it is checked whether reset voltage V_{RST} pulses are continuously generated. If the reset voltage V_{RST} pulses are continuously generated (‘Yes’ direction), the process moves to operation S175. On the other hand, if the reset voltage V_{RST} pulses are not continuously generated (‘No’ direction), the process returns to operation S120.

In operation S175, the number of consecutive reset voltage V_{RST} pulses is counted. For example, a 4-bit counter may be used as a means to count the number of reset voltage V_{RST} pulses.

In operation S180, it is checked whether the number of consecutive reset voltage V_{RST} pulses reaches the maximum value ‘nDN’. When counting the number of reset voltage V_{RST} pulses using a 4-bit counter, the maximum value ‘nDN’ may be 16 (=24). If the number of reset voltage V_{RST} pulses reaches the maximum value ‘nDN’ (‘Yes’ direction), the process moves to operation S182. On the other hand, if the number of reset voltage V_{RST} pulses does not reach the maximum value ‘nDN’ (direction ‘No’), the process returns to operation S120.

In operation S182, the up-and-down counter 1350 of the adaptive OCL controller 1300 is counted down.

In operation S184, when the up-and-down counter 1350 of the adaptive OCL controller 1300 counts down, the up-and-down counter 1350 reduces the size of the OCL control current I_{OCL} of the variable current source 1360.

At operation S186, the reset voltage pulse counter is reset and the procedure returns to operation S120.

In the above, the process of increasing or decreasing the OCL control current I_{OCL} by counting the number of reset voltage V_{RST} and OCL detection voltage V_{OCL} pulses of the adaptive OCL controller 1300 has been described. The oscillator 1400 may generate an oscillation voltage V_{OSC} having a variable switching frequency f_{sw} according to the increasing or decreasing OCL control current I_{OCL}.

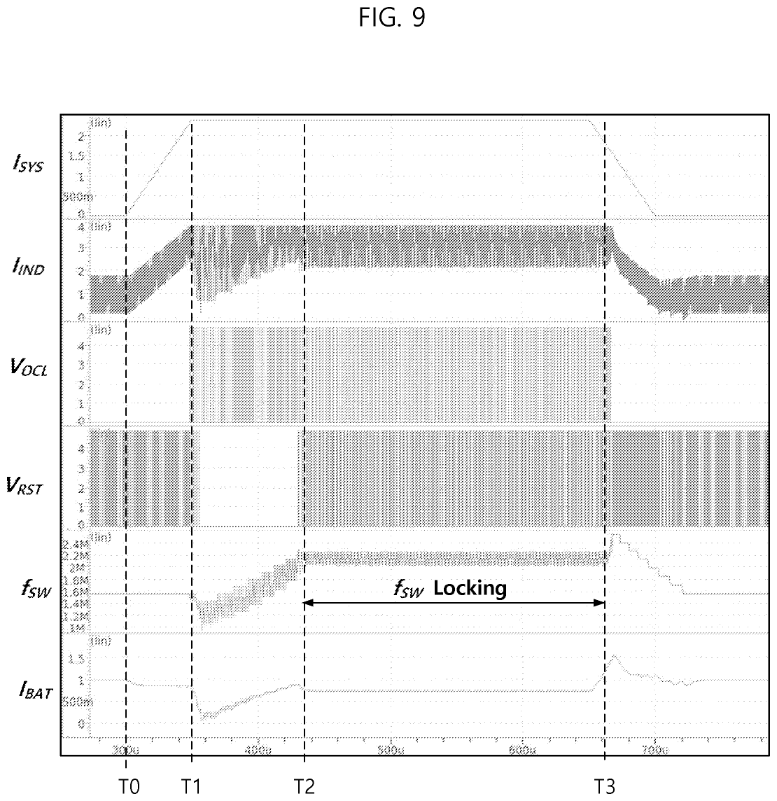

FIG. 9 illustrates the effect of the present disclosure. In FIG. 9, the battery charger IC 1000 may increase the switching frequency f_{SW} of the inductor current I_{IND} when the load current I_{SYS} increases. As the switching frequency f_{SW} increases, the magnitude of the average inductor current I_{IND} can be increased, so the amount of energy delivered to the load can be increased.

At time T0, the load current I_{SYS} required by the system of the mobile device 100 (see FIG. 1) rises. As the load current I_{SYS} increases, the inductor current I_{IND} supplied through switching also increases. However, the reset voltage V_{RST} of the control loop circuit 1100 (see FIG. 2) is generated until the level of the inductor current I_{IND} reaches the OCL level. That is, whenever the ramp voltage V_{RMP} reaches the error voltage V_{ERR} in the control loop circuit 1100, a reset voltage V_{RST} pulse is generated.

From the time point T1, the level of the inductor current I_{IND} starts to reach the OCL level. Then, the error voltage V_{ERR} in the control loop circuit 1100 increases. The reset voltage V_{RST} of the control loop circuit 1100 is generated according to a comparison result between the error voltage V_{ERR} and the ramp voltage V_{RMP}. As the error voltage V_{ERR} becomes higher than the ramp voltage V_{RMP}, generation of the reset voltage V_{RST} is stopped. Instead, the OCL detection voltage V_{OCL} pulse generated when the magnitude of the inductor current I_{IND} reaches the OCL level in the OCL detector (1200, see FIG. 2) starts to be generated.

And, the number of OCL detection voltage V_{OCL} pulses continuously occurring will be accumulated and counted by the adaptive OCL controller (1300, see FIG. 2). As the number of continuously occurring OCL detection voltage V_{OCL} pulses is counted, the magnitude of the OCL control current I_{OCL} starts to increase. Then, the switching frequency f_{sw}, which is the frequency of the oscillation voltage V_{OSC} generated by the oscillator 1400 (see FIG. 2), increases up to the time point T2. At this time, as the switching frequency f_{SW} increases, the level of the charging current I_{BAT} input to the battery 1900 (see FIG. 2) will also begin to gradually recover.

At time T2, the error voltage V_{ERR} starts to decrease again as the switching frequency f_{SW} increases. Generation of the reset voltage V_{RST} starts again by the lowered error voltage V_{ERR}. That is, from the time T2, the OCL detection voltage V_{OCL} and the reset voltage V_{RST} are alternately generated. That is, neither the OCL detection voltage V_{OCL} pulse nor the reset voltage V_{RST} pulse is continuously generated. Accordingly, as the magnitude of the OCL control current I_{OCL} is fixed, locking of the switching frequency f_{SW} occurs from time T2 to time T3 as a result. In addition, the magnitude of the charging current I_{BAT} is also restored to a level similar to that before the rise of the load current I_{SYS}.

At time T3, a generation of the OCL detection voltage V_{OCL} pulse stops as the load current I_{SYS} decreases, and only the reset voltage V_{RST} pulse is generated. Then, as the count number of reset voltage V_{RST} pulses increases, the magnitude of the OCL control current I_{OCL} decreases. As a result, the switching frequency f_{SW} of the inductor current film) will start to decrease from the time point T3.

Because the switching frequency f_{SW} of the inductor current I_{IND} can be increased as the load current I_{SYS} increases, the size of the average inductor current that is switched can be increased. Accordingly, the battery charger IC 1000 of the present disclosure can deliver a lot of energy to the load despite the overcurrent limit for protection.

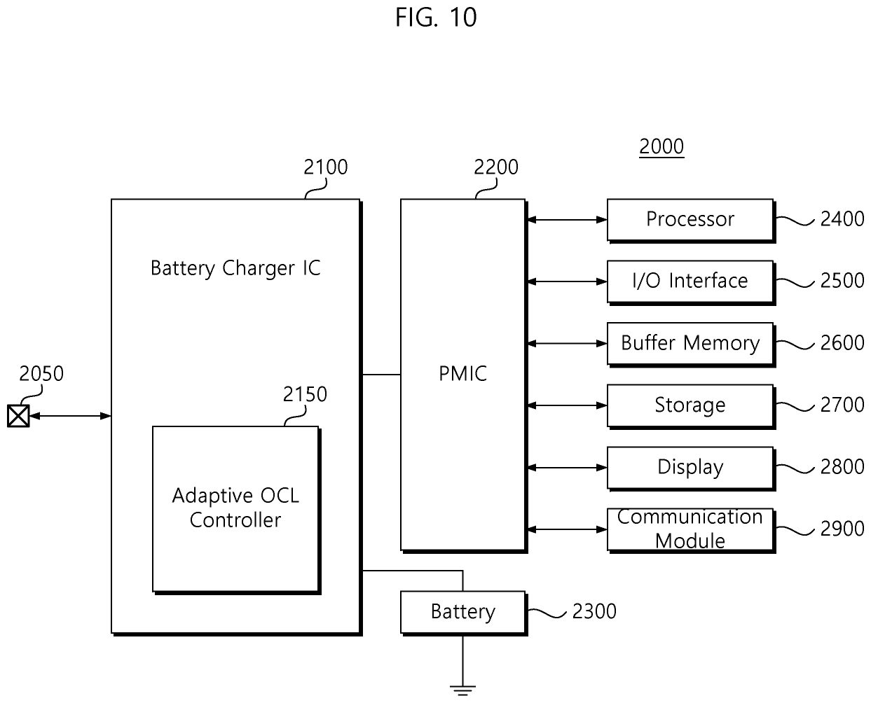

FIG. 10 illustrates a power system of a mobile device according to another embodiment of the present disclosure. In FIG. 10, a power system 2000 may include a battery charger IC 2100, a power management IC 2200, and a battery 2300. The power system 2000 shown in FIG. 10 may further include other components.

The power system 2000 may be used to supply power to a mobile device or to supply power to an OTG device. In the power system 2000, when a travel adapter is connected to the charging terminal 2050, the battery charger IC 2100 operates in a buck mode. That is, in the buck mode, the battery charger IC 2100 operates in a buck converter or charger mode in which the battery 2300 is charged by switching power provided through the travel adapter.

On the other hand, when an OTG device is connected to the charging terminal 2050, the battery charger IC 2100 operates in a boost mode or OTG mode. That is, in the boost mode, the battery charger IC 2100 may switch power charged in the battery 2300 to provide the boosted voltage to the OTG device. Configuration and operations of the battery charger IC 2100 according to an embodiment of the present disclosure may operate as described in FIGS. 1 to 9.

The power management IC 2200 may receive power from the battery charger IC 2100. For example, the power management IC 2200 may convert a voltage provided from the battery charger IC 2100 into a stable voltage. The power management IC 2200 may provide a stable voltage to other components of the mobile electronic device. Each of the processor 2400, the input/output interface 2500, the buffer memory 2600, the storage 2700, the display 2800, and the communication module 2900 included in the mobile electronic device are supplied from the power management IC 2200. It can operate using a stable voltage.

As an example, each of the battery charger IC 2100 or the power management IC 2200 may be implemented as an integrated circuit chip. Each of the battery charger IC 2100 or the power management IC 2200 may be mounted using various types of semiconductor packages. As an example, the battery charger IC 2100 or the power management IC 2200 may include Package on Package (PoP), Ball Grid Arrays (BGAs), Chip Scale Packages (CSPs), Plastic Leaded Chip Carrier (PLCO), and Plastic Leaded Chip Carrier (PDIP). Dual In-line Package), Die in Waffle Pack, Die in Wafer Form, Chip On Board (COB), Ceramic Dual In-line Package (CERDIP), Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), Wafer-Level Processed Stack Package (WSP).

The above are specific embodiments for carrying out the present disclosure. In addition to the above-described embodiments, the present disclosure may include simple design changes or easily changeable embodiments. In addition, the present disclosure will include techniques that can be easily modified and implemented using the embodiments. Therefore, the scope of the present disclosure should not be limited to the above-described embodiments, and should be defined by the claims and equivalents of the claims of the present disclosure as well as the claims to be described later.

What is claimed is:

1. A battery charger integrated circuit for charging a battery, comprising:
an overcurrent limiting detector configured to detect whether a level of an inductor current reaches an overcurrent limiting level and to generate an overcurrent limiting detection voltage;
a control loop circuit configured to generate a reset voltage by comparing a ramp voltage reflecting the level of the inductor current with an error voltage generated based on an operating condition that is out of a preset operating condition;
an adaptive overcurrent limiting controller configured to generate an overcurrent limiting control current by counting a number of pulses of the overcurrent limiting detection voltage and a number of pulses of the reset voltage;
an oscillator configured to generate an oscillation voltage wherein a frequency of the oscillation voltage varies based on a magnitude of the overcurrent limit control current; and
a switching transistor for switching the inductor current based on the oscillation voltage.

2. The battery charger integrated circuit of claim 1, wherein the control loop circuit comprises:
at least one compensator configured to generate an error voltage in a buck mode or a boost mode; and
a ramp generator configured to generate a ramp voltage to which the level of the inductor current is applied.

3. The battery charger integrated circuit of claim 2, wherein the control loop circuit comprises:
a comparator configured to generate the reset voltage based on a level of the ramp voltage that reaches the error voltage.

4. The battery charger integrated circuit of claim 1, wherein the adaptive overcurrent limiting controller comprises:
a first counter configured to count a number of continuously occurring pulses of the overcurrent limit detection voltage;
a first flip-flop configured to generate an up voltage based on a count value of the first counter, which reaches a threshold value;
a second counter configured to count the number of pulses of the reset voltage continuously occurring;
a second flip-flop configured to generate a down voltage based on a count value of the second counter, which reaches the threshold value; and
an up-and-down counter configured to count up in response to the up voltage and counting down in response to the down voltage.

5. The battery charger integrated circuit of claim 4, wherein the adaptive overcurrent limiting controller comprises:
a variable current source configured to generate the overcurrent limiting control current that is variable based on the count value of the up-and-down counter.

6. The battery charger integrated circuit of claim 1, wherein the oscillator comprises:
an oscillation capacitor configured to charge the overcurrent limit control current;
an oscillation current source configured to generate an oscillation current and configured to supply the oscillation current to the oscillation capacitor; and
a comparator configured to generate the oscillation voltage by comparing a sawtooth waveform voltage formed in the oscillation capacitor with an oscillation reference voltage.

7. The battery charger integrated circuit of claim 6, wherein the oscillator comprises:
a discharge switch configured to discharge the current charged in the oscillation capacitor to ground; and
a delay unit configured to delay the oscillation voltage output from the comparator to drive the discharge switch.

8. The battery charger integrated circuit of claim 1, further comprising:
an OR gate configured to perform a logical sum operation of the reset voltage and the overcurrent limit detection voltage; and
an SR latch configured to receive the oscillation voltage through a set input terminal, to receive a result of an OR operation of the OR gate through a reset input terminal, and to generate a duty voltage for driving the switching transistor.

9. An electronic device comprising:
an inductor supplying a charging current supplied from a charging terminal to a battery and a load;
switching transistors configured to switch the inductor current flowing through the inductor based on a duty voltage and configured to transfer the inductor current as a battery current for charging the battery or a load current supplied to the load; and
a battery charger integrated circuit configured to monitor a change in the load current and varying a switching frequency of the inductor current,
wherein the battery charger integrated circuit is configured to increase the switching frequency by counting a number of times that a level of the inductor current reaches an overcurrent limit level.

10. The electronic device of claim 9, wherein the battery charger integrated circuit is further configured to increase the level of the inductor current by varying a duty cycle of the duty voltage based on an increase in the load current.

11. The electronic device of claim 9, wherein the battery charger integrated circuit comprises:
an overcurrent limiting detector configured to detect whether the level of the inductor current reaches the overcurrent limiting level and configured to generate an overcurrent limiting detection voltage;
a control loop circuit configured to generate a reset voltage for varying a duty ratio of the duty voltage by comparing a ramp voltage reflecting the level of the inductor current with an error voltage generated based on an operating condition that is out of a preset operating condition;
an adaptive overcurrent limiting controller configured to generate an overcurrent limiting control current by counting a number of pulses of the overcurrent limiting detection voltage and a number of pulses of the reset voltage; and
an oscillator configured to generate an oscillator voltage wherein a frequency of the oscillator voltage varies based on a magnitude of the overcurrent limit control current.

12. The electronic device of claim 11, wherein the control loop circuit comprises:
at least one compensator configured to generate an error voltage in a buck mode or a boost mode; and
a ramp generator configured to generate an ramp voltage to which the level of the inductor current is applied.

13. The electronic device of claim 12, wherein the control loop circuit further comprises a comparator configured to generate the reset voltage based on a level of the ramp voltage, which reaches the error voltage.

14. The electronic device of claim 11, wherein the adaptive overcurrent limiting controller comprises:
a first counter configured to count a number of continuously occurring pulses of the overcurrent limit detection voltage;
a first flip-flop configured to generate an up voltage based on a count value of the first counter, which reaches a threshold value;
a second counter configured to count a number of pulses of the reset voltage continuously occurring;
a second flip-flop configured to generate a down voltage based on a count value of the second counter, which reaches the threshold value; and
an up-and-down counter configured to count up in response to the up voltage and configured to count down in response to the down voltage.

15. The electronic device of claim 14, wherein the adaptive overcurrent limiting controller further comprises a variable current source configured to generate the overcurrent limiting control current that is variable based on a count value of the up-and-down counter.

16. The electronic device of claim 11, wherein the battery charger integrated circuit comprises:
an OR gate configured to perform a logical sum operation of the reset voltage and the overcurrent limit detection voltage; and
an SR latch configured to receive the oscillation voltage through a set input terminal and receive a result of an OR operation of the OR gate through a reset input terminal, to generate the duty voltage.

17. A method performed by a battery charger integrated circuit, the method comprising:
detecting an increase in a load current;
increasing a duty cycle of a duty voltage for switching an inductor current in response to detecting the increase in the load current;
detecting whether a level of the inductor current reaches a predetermined overcurrent limit level; and
increasing a switching frequency of the duty voltage based on a number of consecutively reaching the predetermined overcurrent limit level of the inductor current, which reaches a predetermined reference number of times.

18. The method of claim 17, further comprising:
generating a reset voltage by comparing a ramp voltage reflecting the level of the inductor current with an error voltage generated based on an operating condition that is out of a preset operating condition, under the increased switching frequency condition.

19. The method of claim 18, further comprising fixing a switching frequency of the duty voltage based on the reset voltage that is generated.

20. The method of claim 18, further comprising reducing the switching frequency based on the number of consecutive occurrences of the reset voltage, which reaches a predetermined number of times.
